(19) United States
(12) Patent Application Publication
(10) Pub. No.: US 2005/0112904 A1
(43) Pub. Date: May 26, 2005

(54) Clean chemistry for tungsten/tungsten nitride gates

(75) Inventors: Herve Y. Kermel, Poughkeepsie, NY (US); Ravikumar Ramachandran, Pleasantville, NY (US)

Correspondence Address: SCULLY SCOTT MURPHY & PRESSER, PC, 400 GARDEN CITY PLAZA, SUITE 300, GARDEN CITY, NY, 11530, US

(73) Assignees: INTERNATIONAL BUSINESS MACHINES CORPORATION, ARMONK, NY (US); INFINEON TECHNOLOGIES OF NORTH AMERICA CORP., SAN JOSE, CA (US)

(21) Appl. No.: 10/718,381

(22) Filed: Nov. 20, 2003

(51) Int. Cl. C23G 1/02; H01L 21/3205; H01L 21/4763; H01L 21/302; H01L 21/461

(52) U.S. Cl. 438/754; 134/3

(57) ABSTRACT

A process and composition for cleaning debris from a stack etch/ion implanted CMOS device which includes a tungsten gate conductor. The composition includes sulfuric acid and hydrogen peroxide in a volume ratio of at least about 6:1. In the process the composition contacts the CMOS device at atmospheric pressure and a temperature of between about 70° C. and about 90° C.

### BACKGROUND OF THE DISCLOSURE

1. Field of the Invention

The present invention is directed to the processing of a complementary metal oxide semiconductor (CMOS) device wherein tungsten is employed in the gate stack. More particularly, the present invention is directed to a process of cleaning CMOS devices utilizing a novel composition.

2. Background of the Prior Art

CMOS devices are commonly employed in the computer industry. CMOS devices utilize a metal oxide semiconductor field effect transistor (MOSFET) which includes a gate structure having a gate insulator formed over a semiconductor substrate upon which a gate electrode is formed to which a voltage is applied to invert the surface of the substrate beneath the electrode forming a channel through which electrons or holes flow from the source towards the drain of the transistor. The gate structure further includes a gate conductor that is electrically connected to the gate electrode by which a gate signal is delivered to the gate electrode.

The material of the gate conductor is typically chosen to be highly conductive to reduce the delay of electrical signal propagation along the gate. Typical gate conductors are characterized by having good electrical conductivity. Thus, elemental metals, metal silicides, certain metal nitrides and their respective alloys and compounds are utilized in this application. At the same time, the gate electrode is chosen to be compatible with a particular transistor design and operation. For instance, the gate electrode work function may be used to adjust the transistor threshold voltage. Typical gate electrodes are comprised of doped polycrystalline silicon where the dopant type (p-type or n-type) is used to adjust thresholds of different transistors. Other doped silicon-containing materials can also be used as gate electrodes. Some examples of silicon-containing gate electrodes, other than polysilicon, include silicon-germanium alloys and metal suicides. This separation of the gate into an electrode layer and a gate conductor layer decouples the material properties needed for high speed signal propagation along the gate and high-performance CMOS transistor design and, as a result, allows for highly conductive gates compatible with high performance CMOS design and operation.

The above remarks establish the need in the art for further increase in electrical conductivity of the gate conductor while preserving the properties of the gate electrode. To that end, highly conductive elemental metals, especially tungsten, have been employed as the gate conductor. In these designs, the tungsten gate conductor is formed over a silicon-containing material, e.g. polysilicon, which acts as the gate electrode. This arrangement, however, because of exposure to high processing temperatures, often causes interdiffusion of the metal with polysilicon which can form, for example, higher resistance materials, such as tungsten silicide. Tungsten silicide has the structural formula WSiₓ, where x is at least 1. The higher resistance of tungsten silicide slows down the signal transport along the gate. In addition, the dopant from the polysilicon can also diffuse into the metal causing reduction of gate electrode dopant activation at the gate dielectric interface.

In view of this phenomena, a conductive barrier is disposed between the highly conductive tungsten material and the silicon-containing material. The conductive barrier acts to avoid intermixing which can lead to degradation of properties of the gate conductor and/or the gate electrode. For example, in contact structures, titanium nitride is used as a barrier between tungsten and silicon to form a W/TiN/Si stack or a W/TiN/TiSi/Si stack after subjecting the contact structure to a moderate temperature sintering anneal at between about 400° C. and about 800° C. wherein a thin layer of titanium forms titanium silicide (TiSi) during annealing. An example of such a structure is provided in U.S. Pat. No. 6,444,516 to Clevenger et al., which is herein incorporated by reference. Specifically, the '516 Patent discloses a gate structure for MOSFET structures wherein a barrier, which may be silicon oxide, silicon nitride (SiNₓ) or silicon oxynitride (SiNₓO_{y}), is located between the tungsten and polysilicon layers. These structures are referred to, for convenience, as W/SiON/polySi structures, wherein SiON refers to any of the barrier layers disclosed in U.S. Pat. No. 6,444,516.

The aforementioned design, wherein a tungsten nitride layer is used as a barrier between the polysilicon and tungsten layers, presents a major problem associated with cleaning the device subsequent to its formation. Although tungsten possesses excellent corrosion resistance in acid compositions, such a cleaning composition cannot be utilized in photoresist and post photoresist stripping applications. These cleaning steps require a combination of acid and oxidizer to effectively remove the resist layer. However, the inclusion of an oxidizer, usually hydrogen peroxide, with an acid, unfortunately, enhances the rate at which tungsten is etched. Thus, mixtures of acid and oxidizer employed in the processing of prior art CMOS devices, although essential to remove carbon-containing and etch residues, also removes tungsten. Tungsten removal reduces gate conductor electrical conductivity so that sheet resistance is increased to the point that the resultant device misses design targets and performance assigned to that CMOS.

The above remarks establish the strong need in the art for a new cleaning composition and a process of employing the same in the cleaning of CMOS devices which utilize tungsten and tungsten nitride therein.

### SUMMARY OF THE INVENTION

A new composition has now been developed for use in cleaning of gates of MOSFET structures used in CMOS devices wherein a tungsten/tungsten nitride gate is utilized. This new process of utilizing this composition permits excellent removal of carbon-containing and etch residues without attendant deminishment in CMOS properties.

In accordance with the present invention, a process is provided for removing carbon-containing and etch residue from a complementary metal oxide semiconductor device which includes a tungsten gate conductor. In this process, the CMOS, which includes a tungsten gate conductor subjected to stack etch/ion implantation steps followed by resist stripping, is contacted with a composition which includes sulfuric acid and hydrogen peroxide, present in a volume ratio of at least about 6:1, at atmospheric pressure and a temperature of between about 70° C. and about 90° C.

In further accordance with the present invention, a new composition is provided which comprises sulfuric acid and hydrogen peroxide present in a concentration such that the volume ratio of sulfuric acid to hydrogen peroxide is at least about 6:1.

### DETAILED DESCRIPTION

In accordance with usual fabrication techniques, a CMOS device employing a MOSFET structure including a gate having a gate insulator formed over a semiconductor substrate is utilized in the present invention. The MOSFET structure includes tungsten as the gate electrode and a tungsten nitride layer which acts as a barrier between the polysilicon and tungsten layers. The purpose of this barrier layer is to prevent the formation of tungsten silicide.

After the structuring of the tungsten gate, the halo and extension device implants are done. A photoresist mask is typically used for those ion implantation steps.

Thereupon, the photoresist is stripped off in a plasma operation. This is followed by a wet post clean operation during which W is exposed. It is the post clean operation which is the subject of the improved process of the present invention. That is, in the past the post clean operation, necessary to remove carbon-containing as well as etch residues, employed cleaning compositions which, although effective with other CMOS devices, resulted in significant tungsten etching when tungsten was the gate conductor. The cleaning process of the present invention does not result in significant tungsten etching..

The carbon-containing and etch residue removal step involves contact of the CMOS with a cleaning composition which includes sulfuric acid and hydrogen peroxide present in a volume ratio of at least about 6:1. More preferably, the cleaning composition of the present invention utilizes sulfuric acid and hydrogen peroxide present in a volume ratio of between about 6:1 and about 100:1. Still more preferably, the volume ratio of sulfuric acid to hydrogen peroxide is in the range of about 6:1 and about 10:1. Most preferably, the volume ratio of sulfuric acid to hydrogen peroxide is about 8:1.

The preferred maximum volume ratio of sulfuric acid to hydrogen peroxide of about 100:1, it is emphasized, is not the maximum operable ratio. Indeed, the upper range of this ratio is theoretically unlimited. However, as this volume ratio increases, the cleaning efficiency decreases. Therefore, the maximum ratio is dependent of the amount of residue linked to the photoresist removal process. In addition, when hydrogen peroxide is present in a volume ratio of less than 1 part by volume hydrogen peroxide per 100 parts by volume sulfuric acid, the duration of time required to remove residue may become too long to support commercial utilization.

The cleaning composition in a preferred embodiment is free of any other components. That is, the cleaning composition in this preferred embodiment consists essentially of sulfuric acid and hydrogen peroxide, the only other components present being impurities present in the separate sulfuric acid and hydrogen peroxide streams.

In the aspect of the invention wherein the cleaning composition is employed in the removal of carbon containing and etch residue from a tungsten/tungsten nitride gate CMOS, the composition is preferably prepared by separately introducing a sulfuric acid and a hydrogen peroxide stream, so that in-situ mixing occurs, into a flow controlling device upstream of the point of contact with the CMOS device so that the two streams are monitored to provide a cleaning composition which contacts the CMOS device comprising only those two streams and only in the desired volume ratio. As such, the composition consists essentially of those streams insofar as the only other constituents of the cleaning composition are inert components, principally water, present in the sulfuric acid and hydrogen peroxide streams.

In an alternate embodiment of the process of the present invention the sulfuric acid and hydrogen peroxide components are premixed in bulk to form the cleaning composition, in the desired volume ratio, and that composition contacts the CMOS device.

The process of cleaning the CMOS device occurs at atmospheric pressure and a temperature in the range of between about 70° C. and about 90° C. Processing occurs over a period of time in the range of between about 1 minute and about 10 minutes. More preferably, the processing duration occurs over between about 2 minutes and about 5 minutes.

The following examples are given to illustrate the scope of the present invention. Because these examples are given for illustrative purposes only, the invention should not be deemed limited thereto.

### EXAMPLE 1

A cleaning composition is formed from a sulfuric acid stream having a sulfuric acid content of 96.5%±1.5% and a hydrogen peroxide stream having a hydrogen peroxide concentration of 31%±1%, the remainder of both streams being substantially all water. The two streams are metered together, employing a flow controller, to provide a volume ratio of 8:1, sulfuric acid to H₂O₂. The thus formed cleaning composition is applied to a CMOS device employing a tungsten/tungsten nitride gate stack subsequent to photoresist application, ion implantation and photoresist stripping. That is, the thus formed cleaning composition is applied as a means of removing carbon-containing and etch residues formed during the CMOS device forming processing steps.

The cleaning composition is applied as a two-phase fluid by entraining the metered cleaning composition with inert nitrogen gas. The two-phase composition, applied as a mist, is applied under ambient pressure and a temperature of about 80° C. Contact of the cleaning composition on the CMOS device is maintained for about 4 minutes.

The aforementioned cleaned CMOS device is investigated to determine the degree of tungsten etching. It is discovered that the rate of tungsten removal, e.g. etching, is less than 2 nanometers per minute. This value is calculated based on sheet resistivity data calibrated against known thickness standards.

### COMPARATIVE EXAMPLE 1

A CMOS device identical to the device cleaned in Example 1 is cleaned by applying a composition comprising the same sulfuric acid and hydrogen peroxide streams employed in Example 1. The two streams were metered together and applied as a two-phase mist utilizing nitrogen gas as the entraining gas phase. The thermodynamic conditions and time duration under which the cleaning solution is applied are identical to that employed in Example 1. The sole distinction is that the volume ratio of sulfuric acid to hydrogen peroxide is 4:1.

The CMOS device is investigated to determine the degree of tungsten etching. It is determined that the etching rate is approximately 875 nm/min.

In fact, this rate is consistent with substantially the complete removal of all the tungsten present in the gate conductor.

### COMPARATIVE EXAMPLE 2

An identical CMOS device to the device of Example 1 is cleaned under the same thermodynamic conditions and time duration employed in Example 1. However, in this example, the cleaning composition comprises only the sulfuric acid stream employed in the cleaning composition of Example 1. That is, the cleaning composition contains no hydrogen peroxide.

An analysis of the resulting CMOS produced by this cleaning composition indicates the absence of tungsten etching. However, the carbon-containing and etch debris present on the surface below the gate stacks of CMOS is undisturbed. That is, no carbon-containing or etch residue is removed.

The above examples and embodiments are given to illustrate the scope and spirit of the present invention. These examples and embodiments will make apparent, to those skilled in the art, other embodiments and examples. These other embodiments and examples are within the contemplation of the present invention. Therefore, the present invention should be limited only by the appended claims.

1. A process of removing residue from a complementary metal oxide semiconductor (CMOS) device which includes a tungsten gate conductor which has been subject to stack etch/ion implantations and photoresist stripping steps comprising the step of contacting a CMOS device which includes a tungsten gate conductor with a cleaning composition comprising sulfuric acid and hydrogen peroxide present in a volume ratio of at least about 6:1, said contact occurring at atmospheric pressure and a temperature of between about 70° C. and about 90° C.

2. A process in accordance with claim 1 wherein said volume ratio of said sulfuric acid to said hydrogen peroxide is at least about 6:1 and about 100:1.

3. A process in accordance with claim 1 wherein said volume ratio of sulfuric acid to hydrogen peroxide is in the range of between about 6:1 and about 10:1.

4. A process in accordance with claim 1 wherein said volume ratio of sulfuric acid to hydrogen peroxide about 8:1.

5. A process in accordance with claim 1 wherein contact of said composition with said CMOS device occurs over a period of between about 1 minute and about 10 minutes.

6. A process in accordance with claim 5 wherein said period of time is in the range of between about 2 minutes and about 5 minutes.

7. A process in accordance with claim 1 comprising pre-mixing of said sulfuric acid and said hydrogen peroxide whereby said cleaning composition is formed.

8. A process in accordance with claim 1 comprising in-situ mixing of said sulfuric acid and said hydrogen peroxide whereby said cleaning composition is formed.

9. A process in accordance with claim 1 wherein said cleaning composition consists essentially of sulfuric acid and hydrogen peroxide.

10. A composition which comprises sulfuric acid and hydrogen peroxide present in a volume ratio of at least about 6:1.

11. A composition in accordance with claim 10 wherein said volume ratio is in the range of between 6:1 and about 100:1.

12. A composition in accordance with claim 11 wherein said volume ratio is in the range of between about 6:1 and about 10:1.

13. A composition in accordance with claim 12 wherein said volume ratio is about 8:1.

14. A composition which consists essentially of sulfuric acid and hydrogen peroxide present in a volume ratio of at least about 6:1.

15. A composition in accordance with claim 14 wherein said volume ratio is in the range of between about 6:1 and about 100:1.

16. A composition in accordance with claim 15 wherein said volume ratio is in the range of between about 6:1 and about 10:1.

17. A composition in accordance with claim 16 wherein said volume ratio in about 8:1.
